(19) United States
(12) Patent Application Publication
(10) Pub. No.: US 2005/0239223 A1
(43) Pub. Date: Oct. 27, 2005

(54) Method and device for monitoring the etching operation for a regular depth structure in a semiconductor substrate

(75) Inventors: Ulrich Mantz, Dresden (DE); Thomas Hingst, Dresden (DE); Stephan Wege, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 11/106,726

(22) Filed: Apr. 15, 2005

(30) Foreign Application Priority Data
Apr. 16, 2004 (DE) 10 2004 018 454.2

(51) Int. Cl. H01L 21/66

(52) U.S. Cl. 438/14; 438/16

(57) ABSTRACT

In order to monitor the etching operation for a regular depth structure in a semiconductor substrate, a radiation source is used to irradiate, in large-area fashion, the semiconductor substrate in the region of the depth structure during the etching operation at a predetermined angle of incidence with respect to the surface of the semiconductor substrate with an electromagnetic radiation whose wavelength lies in the infrared region, a radiation detector is used to continuously detect the intensity of the reflected radiation at an angle of reflection—corresponding to the angle of incidence—with respect to the surface of the semiconductor substrate, and an evaluation unit is used to determine the depth of the etched structure and/or the quality of the etched structure with regard to the regularity thereof from the recorded intensity profile.

### CLAIM FOR PRIORITY

This application claims priority to German Application No. 10 2004 018 454, filed Apr. 16, 2004, which is incorporated herein, in its entirety, by reference.

### TECHNICAL FIELD OF THE INVENTION

The invention relates to a method and a device for monitoring the etching operation for a regular depth structure in a semiconductor substrate.

### BACKGROUND OF THE INVENTION

Semiconductor memories, in particular dynamic random access semiconductor memories (DRAM), are composed of a matrix of memory cells which are connected up in the form of rows via word lines and columns via bit lines. The read-out of the data from a memory cell or the writing of the data to a memory cell is realized by activation of the corresponding word line and bit line.

It is an objective of DRAM memory development to achieve a highest possible yield of memory cells with good functionality in conjunction with minimal chip size. Continual endeavours to miniaturize the DRAM memory cells, which are composed of a selection transistor and a storage capacitor, have led to the design of memory cell layouts in which, in particular, the storage capacitor utilizes the third dimension.

One such three-dimensional storage capacitor concept is trench capacitors, which are in each case formed in a trench etched into a semiconductor substrate. In this case, the trench is filled with a highly conductive material that serves as inner capacitor electrode. By contrast, the outer capacitor electrode is generally formed as a diffusion zone around the lower trench region in the semiconductor substrate. In order to be able to make the cell size as small as possible and at the same time to provide for a sufficient storage capacitance that ensures a sufficiently large read signal of the DRAM memory cell, the trench capacitors are being fabricated with increasingly deeper trenches. Furthermore, the trench capacitors of the DRAM memory cells are being packed more and more densely in order thus to further reduce area required by the individual memory cells.

The ongoing miniaturization of the trench capacitors whilst at the same time lengthening the trench depth is also accompanied by an increase in particular in the requirements made of the precision of the etching process for forming the trenches. At the same time, a rapid and effective monitoring method is also necessary in order to be able to precisely determine the quality of the etched trenches and the geometrical extent thereof. In this case, great importance is accorded in particular to the determination of the depth of the etched trenches since this parameter has a significant influence on the storage capacitance of the trench capacitor and thus on the functionality of the DRAM memory cell. What is more, deviations in the regularity of the trenches may lead to malfunctions in the trench capacitors, which in turn adversely affects the functioning of the DRAM memory, so that great importance is also accorded to the determination of the quality of the etched trench structure.

In order to be able to determine the depth of the etched trenches or to assess the quality of the etched trenches, test wafers have generally been fractured in the region of the etched trench structure and examined with the aid of a scanning electron microscope. The depth of the trench structure or deviations from the desired trench form could then be determined on the basis of the scanning of the fractured edge. However, this measurement method proves to be complicated and time-consuming due to the necessary fracturing of the test wafers. What is more, the semiconductor wafer is destroyed as a result of the fracturing process, which makes the measurement method extremely cost-intensive. Moreover, it is not possible with this measurement method to make a statement about the etching quality or the attained depth continuously during the etching process.

### SUMMARY OF THE INVENTION

The invention provides a non-destructive, cost-effective and rapid method and a corresponding device for determining the depth and quality of an etched structure in a semiconductor wafer.

In accordance with one embodiment of the invention, in order to monitor the etching operation for a regular depth structure in a semiconductor substrate, the semiconductor substrate is irradiated during the etching operation in large-area fashion in the region of the depth structure at a predetermined angle of incidence with respect to the surface of the semiconductor substrate with an electromagnetic radiation whose wavelength lies in the infrared region. At the same time, the intensity of the reflected radiation at an angle of reflection—corresponding to the angle of incidence—with respect to the surface of the semiconductor substrate is continuously detected and the depth of the etched structure and/or the quality of the etched structure with regard to the regularity thereof is then determined from the recorded intensity profile.

The procedure according to the invention and the correspondingly designed device make it possible to determine the depth of a trench structure and the quality thereof non-destructively. Furthermore, the procedure according to the invention can be applied directly to a product wafer and be carried out directly during the fabrication method, so that the procedure according to the invention enables an ongoing determination of the depth or quality of the etching and thus also an end point determination for the etching operation.

In accordance with one preferred embodiment, the determination of the depth of the etched structure and/or of the quality of the etched structure with regard to the regularity thereof is effected by comparison of the measured intensity profile with a reference intensity profile, which has been determined e.g. on test wafers, the depth in each case being additionally confirmed by a scanning electron microscope recording.

As an alternative, however, it is also possible to calculate the reference intensity profile on the basis of a model, in which case, on the basis of the known optical properties of the material of the semiconductor substrate and the desired structure dimensions produced during the etching, a prediction for the intensity of the electromagnetic radiation reflected at the surface of the semiconductor substrate is made, depending on the structure depth.

### BRIEF DESCRIPTION OF THE DRAWINGS

The invention is explained in more detail below with reference to the accompanying drawings, in which:

FIG. 1 shows a sectional illustration through a semiconductor substrate with a regular trench structure for elucidating the measurement method according to the invention.

FIG. 2 shows a measurement arrangement according to the invention.

### DETAILED DESCRIPTION OF THE INVENTION

The invention is explained on the basis of a trench structure such as is used in the context of a DRAM memory chip for forming storage capacitors. However, it can be used for monitoring the etching operation of arbitrary depth structures in a semiconductor substrate.

DRAM memory chips are preferably formed with the aid of the silicon planar technique, which comprises a sequence of individual processes that in each case act over the whole area of the surface of a silicon wafer, local alterations of the silicon substrate being carried out in a targeted manner by means of suitable masking steps. In this case, a multiplicity of structures can be formed simultaneously in the context of the planar technique.

In order to form the trenches for storage capacitors, a masking layer is deposited on a silicon wafer 1 freed of impurities, which has generally already undergone various patterning processes, the desired regular trench capacitor structure subsequently being defined on said masking layer with the aid of lithography technology. For this purpose, a light-sensitive layer is applied to the masking layer and exposed with the aid of a mask having the structure of a design plane of the trenches to be formed. After development, i.e. the removal of the exposed photoresist, the masking layer is etched with the aid of an anisotropic etching in order to produce an etching mask for the trench etching.

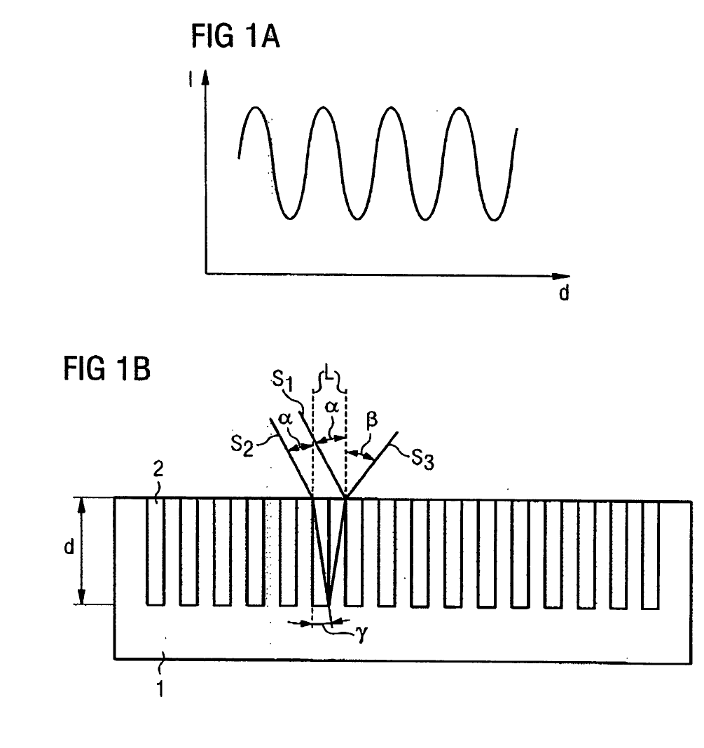

After the residual photoresist mask has been eliminated, said trench etching is then carried out. For this purpose, the silicon substrate is etched anisotropically with the aid of the patterned etching mask, down to a desired depth of, for example, 5 μm given a structure width of, for example 0.5 μm, thus giving trenches 2 having an aspect ratio, i.e. a width-depth ratio, of 1:10. FIG. 1 shows a cross section through the silicon wafer 1 after the trench etching, in the case of which a multiplicity of closely adjacent trenches 2 have been formed.

The quality of the etched trenches is significant for the electrical properties of the storage capacitors formed in these trenches and thus for the functionality of the DRAM memory. In this case, it is crucial, in particular, to be able to precisely determine the depth of the etched trenches, which in turn define the storage capacitance. At the same time, it is desirable to be able to make statements about the quality of the etched structure in particular about the regularity of the etched trenches, since deviations may adversely affect the functionality of the DRAM memory.

The measurement method according to the invention and the corresponding measuring device enable the depth of the trenches produced and the quality of the trench pattern to be continuously determined during the etching operation. Furthermore, according to the invention, the monitored etching process can then be controlled such that a desired depth is set exactly. The principle of the measurement method according to the invention is explained below with reference to FIG. 1.

An electromagnetic radiation having a wavelength in the infrared region is radiated onto the silicon wafer 1 in large-area fashion at a predetermined angle of incidence with respect to the surface of the silicon substrate 1 during the etching process for forming the trenches. In this case, FIG. 1 shows a snapshot during the etching process, the radiation being indicated by two beams S1 and S2. The use of an electromagnetic radiation having a wavelength in the infrared region proves to be advantageous in order to be able to determine a depth spectrum of the trench structure which extends right into a depth of a number of μm. In contrast to radiation having a wavelength in the optically visible region, the radiation in the infrared region is distinguished by low absorption and thus a high penetration depth, in particular in the silicon substrate. Since, moreover, the wavelength of the radiation is significantly greater than the lateral dimension of the etched trenches, scattering effects that would otherwise result are essentially suppressed.

If, as shown in FIG. 1, the infrared radiation impinges on the surface of the silicon substrate at an angle α of incidence with respect to a perpendicular L, then a part of the radiation represented by the partial beam S1 is reflected from the silicon surface at an angle β of reflection corresponding to the angle α of incidence. Another part of the radiation, represented by the partial beam S2, penetrates into the silicon substrate and is refracted at an angle γ of refraction toward the perpendicular. Since the silicon substrate 1 in the region of the etched trenches differs with regard to its material composition, silicon and empty regions alternate here, from the underlying silicon substrate, which is composed completely of silicon, a further interface results between the section of the silicon substrate with the etched trenches and the underlying silicon, which leads to a reflection of the partial beam S2 at the interface. Said partial beam is then refracted away from the perpendicular L again at the angle β of reflection at the surface of the silicon substrate 1. The reflected partial beams S1 and S2 are superposed and form an interference beam S3, the resulting intensity depending on the distance between the interfaces, i.e. the etching depth d, at which the two partial beams S1 and S2 are reflected.

FIG. 1 further schematically illustrates an intensity profile I of the reflected radiation as a function of the etching depth d. Depending on the etching depth of the trenches and thus the distance between the interfaces at which the partial beams S1 and S2 are reflected, the result in this case is a constructive or destructive interference of the reflected partial beams, the distance between the successive maxima or minima depending on the wavelength of the infrared radiation and the precise material composition between the two interfaces. The intensity value itself in turn or the difference between maximum and minimum intensity values is furthermore a measure of the quality of the interfaces and thus of the regularity of the trench pattern scanned by means of the radiation.

In order to be able to precisely determine the etching depth, it is possible to compare the measured etching profile with a reference profile which has been recorded on a test wafer having the same material composition and for which the depth associated with the respective intensity value has in each case additionally been determined with the aid of a further measurement method, e.g. by means of a scanning electron microscope examination. It is furthermore possible to calculate the reference profile using a model on the basis of the known wavelength of the infrared radiation that is radiated in and the material composition produced by the etching operation in the region between the two reflective interfaces in the silicon substrate and then to compare this model reference profile with the measured etching profile in order thus to determine the respective etching depth.

Furthermore, the etching depth may also be calculated directly from the measured etching profile whilst taking account of the wavelength and the material composition between the two reflective interfaces of the silicon substrate. In order to be able to determine the quality of the etched trench structure, in particular a measure of its regularity, from the measured intensity profile, the measured intensity spectrum is again preferably compared with a reference spectrum which has been determined on a test structure, the regularity of the test structure having been ascertained by means of a further measurement method, e.g. a scanning electron microscope.

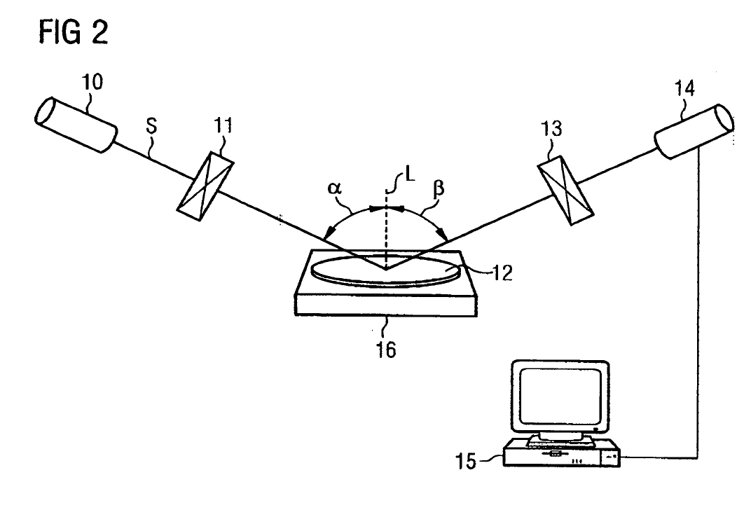

FIG. 2 shows a measurement arrangement for carrying out the method according to the invention. The measurement arrangement has a radiation source 10, which emits the electromagnetic radiation S in the infrared region. An infrared laser is preferably used as radiation source 10 in this case. The radiation emerging from the radiation source 10 is expanded with the aid of an optical system 11 and directed onto the semiconductor substrate 12 arranged on a holder 16. The radiation reflected from there is in turn detected by means of a further optical system 13 and conducted onto a radiation detector 14, which detects the intensity of the reflected radiation and transfers it to an evaluation unit 15, which then determines, from the continuously detected intensity, the depth of the etched structure or the quality thereof on the basis of a comparison with a reference intensity profile or by direct calculation.

In this case, the measurement arrangement illustrated in FIG. 2 is designed such that the angle α of incidence of the radiation on the surface corresponds to the angle β at which the reflected radiation is detected. In this case, it is also possible, e.g. with the aid of a semitransparent mirror which is incorporated into the beam path and via which the reflected radiation is deflected, to perform perpendicular radiating onto the silicon substrate and then also to detect the perpendicularly reflected radiation.

It is furthermore possible for the evaluation unit 15 to control the etching operation (etching apparatus not shown) in real time on the basis of the etching depth respectively determined, in order thus to perform an exact end point determination for the etching operation at the desired depth.

1. A method for monitoring an etching operation for a regular depth structure in a semiconductor substrate, comprising:
large-area irradiating of the semiconductor substrate in a region of the depth structure during the etching operation at a predetermined angle of incidence with respect to a surface of the semiconductor substrate with an electromagnetic radiation whose wavelength lies in an infrared region;
continuously detecting of an intensity of reflected radiation at an angle of reflection, corresponding to the angle of incidence, with respect to the surface of the semiconductor substrate; and
determining the depth of the etched structure and/or of a quality of the etched structure with regard to regularity thereof from the recorded intensity profile.

2. The method as claimed in claim 1, the determination of the depth of the etched structure and/or of the quality of the etched structure with regard to the regularity thereof being effected by comparison of the recorded intensity profile with a reference intensity profile.

3. The method as claimed in claim 2, the reference intensity profile being an intensity profile calculated based on a model.

4. A device for monitoring an etching operation for a regular depth structure in a semiconductor substrate, comprising:
a radiation source for large-area irradiation of the semiconductor substrate in a region of the depth structure during the etching operation at a predetermined angle of incidence with respect to a surface of the semiconductor substrate with an electromagnetic radiation whose wavelength lies in an infrared region;
a radiation detector for continuous detection of the intensity of reflected radiation at an angle of reflection, corresponding to the angle of incidence, with respect to the surface of the semiconductor substrate; and
an evaluation unit for determination of the depth of the etched structure and/or of a quality of the etched structure with regard to regularity thereof from the recorded intensity profile.

5. The device as claimed in claim 4, further comprising a laser being used as radiation source.

6. A method for monitoring an etching operation for a regular depth structure in a semiconductor substrate, comprising:
continuously irradiating of the semiconductor substrate in a region of the depth structure during the etching operation at a predetermined angle of incidence with respect to a surface of the semiconductor substrate with an electromagnetic radiation whose fixedly predetermined wavelength lies in an infrared region;
continuously detecting of intensity of the reflected radiation at an angle of reflection, corresponding to the angle of incidence, with respect to the surface of the semiconductor substrate; and
continuously determining the depth of the etched structure and/or of the quality of the etched structure with regard to regularity thereof from the continuously recorded intensity profile.
